(19) United States
(12) Patent Application Publication
(10) Pub. No.: US 2026/0371944 A1
(43) Pub. Date: Nov. 19, 2026

(54) PHASE-CHANGE MATERIAL (PCM) RADIO FREQUENCY (RF) SWITCHING DEVICE WITH AIR GAP AND METHOD FOR FABRICATING THE SAME

(71) Applicant: Taiwan Semiconductor Manufacturing Company, Ltd., Hsinchu (TW)

(72) Inventors: Kuo-Pin Chang, Hsinchu (TW); Yu-Wei Ting, Taipei (TW); Yi Ching Ong, Hsinchu (TW); Kuo-Ching Huang, Hsinchu (TW); Harry-Hak-Lay Chuang, Hsinchu (TW)

(21) Appl. No.: 19/754,341

(22) Filed: Jul. 27, 2026

Related U.S. Application Data
(62) Division of application No. 17/851,026, filed on Jun. 28, 2022.

(51) Int. Cl. H10N 70/00; H01H 37/46; H10B 63/00; H10N 70/20; H10W 44/20

(52) U.S. Cl. CPC H10N 70/8613; H01H 37/46; H10B 63/80; H10N 70/023; H10N 70/026; H10N 70/063; H10N 70/231; H10N 70/823; H10N 70/8828; H10W 44/20; H10W 44/203

(57) ABSTRACT

A method of fabricating a phase-change material (PCM) switching device is provided. The method includes providing a base dielectric layer and forming a first heater element having a first coefficient of thermal expansion (CTE) on the base dielectric layer. A second heater element having a larger second CTE is formed on the first heater element. First and second metal pads are formed on the base dielectric layer lateral to first and second sides of the heater elements, defining first and second air gap portions, respectively. A PCM region is then formed on the first and second metal pads and suspended above a top surface of the second heater element, defining a third air gap portion between the PCM region and the second heater element. The PCM region switches between an amorphous state and a crystalline state in response to heat generated by the heater elements.

### CROSS-REFERENCE TO RELATED APPLICATIONS

The application is a divisional application of U.S. non-provisional patent application Ser. No. 17/851,026 filed Jun. 28, 2022, the entire disclosure of which is incorporated herein by reference.

### FIELD

Embodiments of the present disclosure relate generally to radio frequency (RF) devices, and more particularly to phase-change material (PCM) RF switching devices.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. There is always a need to improve the performance of semiconductor devices.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a diagram illustrating an example phase-change material (PCM) radio frequency (RF) switch in accordance with some embodiments.

FIG. 1B is a diagram illustrating the cross-section of the PCM RF switch shown in FIG. 1A in accordance with some embodiments.

FIG. 1C is a diagram illustrating the cross-section of the PCM RF switch shown in FIG. 1A during a write operation in accordance with some embodiments.

FIG. 2 is a diagram illustrating soft reset that can be prevented in accordance with some embodiments.

FIG. 3 is a diagram illustrating an example equivalent circuit of the PCM region in accordance with some embodiments.

FIG. 4 is a flowchart diagram illustrating an example method for fabricating a PCM RF switch in accordance with some embodiments.

FIGS. 5A-5H are cross-sectional views of a portion of the PCM RF switch at various stages of fabrication in accordance with some embodiments.

FIG. 6 is a flowchart diagram illustrating an example method for operating a PCM RF switch in accordance with some embodiments.

### DETAILED DESCRIPTION OF THE INVENTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In addition, source/drain region(s) may refer to a source or a drain, individually or collectively dependent upon the context. For example, a device may include a first source/drain region and a second source/drain region, among other components. The first source/drain region may be a source region, whereas the second source/drain region may be a drain region, or vice versa. One of ordinary skill in the art would recognize many variations, modifications, and alternatives.

Some embodiments of the disclosure are described. Additional operations can be provided before, during, and/or after the stages described in these embodiments. Some of the stages that are described can be replaced or eliminated for different embodiments. Some of the features described below can be replaced or eliminated and additional features can be added for different embodiments. Although some embodiments are discussed with operations performed in a particular order, these operations may be performed in another logical order.

A radio frequency (RF) switch or a microwave switch (sometimes also referred to as an “RF switching device” or a “microwave switching device”) is a device to route high-frequency signals through transmission paths. RF or microwave switches are used extensively in microwave test systems for signal routing between instruments and devices under test (DUT). In addition, RF switches are widely used in wireless communication.

A phase-change material (PCM) RF switch is a new type of RF switch. PCM RF switches operate based on the PCM switching mechanism. The PCM switching mechanism is a mechanism of reversible switching of a PCM between resistive states, i.e., an amorphous OFF state (i.e., a high resistance state) and a crystalline ON state (i.e., a low resistance state). The reversible switching is enabled by changing the phase of the PCM, which includes a structure that may change phase between amorphous and crystalline based on, for example, temperature change sequences via joule heating. Joule heating involves the heat that is produced during the flow of an (electric) current through, for example, a conductive material. As the PCM changes phase from crystalline to amorphous, for example, due to heating and cooling sequences controlled by, for example, applied voltage biases from the control circuitry, the resistance of the PCM changes from low to high, respectively. Accordingly, a PCM RF switch can be turned on or off by switching between the high resistance state and the low resistance state.

Joule heating is typically controlled by temperature pulses (implemented by current pulses) with the desired pulse width and the desired falling time. In the reset operation (i.e., changing from the crystalline state to the amorphous state), a high current is used to raise the temperature of the PCM above its melting temperature, with a fast cooling (i.e., a short falling time) to quench the PCM to prevent re-crystallization. In the set operation (i.e., changing from the amorphous state to the crystalline state), a medium current is used to raise the temperature of the PCM above its crystallization temperature but below its melting temperature. The pulse width is relatively long for nucleation formation, while the falling time is relatively long for crystal growth.

In some implementations, a dielectric layer, such as a silicon nitride (SiN) layer, is inserted between the PCM and a heater element to insulate the heater element and the PCM and prevent phase segregation (i.e., change in PCM composition) after multiple cycles. Therefore, the Joule heating is indirect heating because of the presence of the silicon nitride layer. Indirect heating requires more power for switching. Thus, the efficiency of thermal transmission may be compromised.

The silicon nitride layer typically has a larger area than the heater element (i.e., extending horizontally beyond the heater element), and a portion of the heat that is generated by the heater element during the write operation is dissipated laterally instead of vertically. Thus, there is lateral thermal loss, and the power consumption during the write operation increases. The efficiency of thermal distribution is compromised.

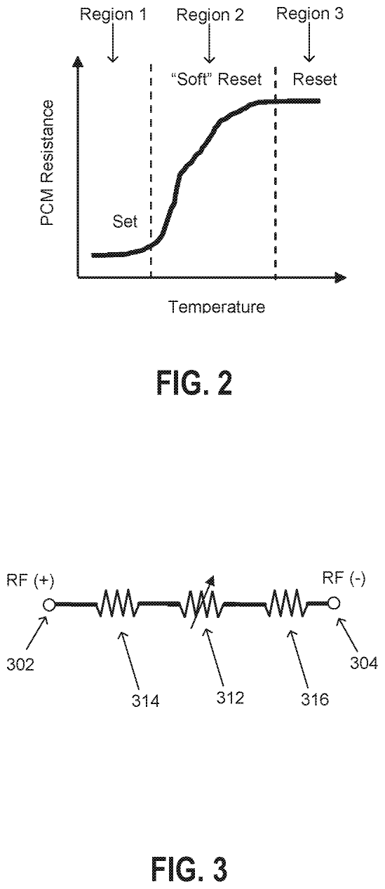

Additionally, the lateral thermal dissipation results in a portion of the PCM that is not on the heater element not being fully reset (i.e., not fully amorphous, sometimes also referred to as “soft reset”) because the temperature there rises but does not reach the melting temperature. The soft reset portion of the PCM may contribute to the parasitic resistance. Soft reset will be described in greater detail below with reference to, for example, FIG. 2.

Lastly, the extended silicon nitride layer also results in a large parasitic capacitance. A large parasitic capacitance negatively impacts the isolation in the OFF state (i.e., the attenuation of the undesired signal in the OFF state) of the PCM RF switch.

In accordance with some aspects of the disclosure, a phase-change material (PCM) switching device is provided. The PCM switching device includes a double-layered heater element and an air gap surrounding three sides of the double-layered heater element. In one embodiment, the double-layer heater element includes a first heater element comprising a first metal element and a second heater element comprising a second metal element. The first metal element is characterized by a first coefficient of thermal expansion (CTE), and the second metal element is characterized by a second CTE larger than the first CTE. In the write operation, the second heater element deforms, and a top surface of the second heater element protrudes upwardly toward the PCM region, which comprises a PCM. As such, a heat dissipation path is created. The PCM is switched between an amorphous state and a crystalline state in response to the heat generated. The PCM switching device is switched accordingly.

First, the efficiency of thermal distribution is increased because of the presence of the air gap and the double-layered heater element. There is no conventional dielectric layer between the double-layered heater element and the PCM region. As a result, no heat that is generated by the double-layered heater element is absorbed by the conventional dielectric layer. Moreover, since only the tip and a small region near the tip of the top surface of the second heater element are in contact with the bottom surface of the PCM region, lateral thermal dissipation is suppressed. Accordingly, the intended thermal transmission in the vertical direction is more concentrated or focused, the thermal transmission efficiency is further increased. The power needed during the write operation is reduced accordingly.

Second, the off-state capacitance is reduced. Due to the presence of the air gap (characterized by a relatively low dielectric constant of about 1) instead of the silicon nitride layer made of silicon nitride (characterized by a relatively high dielectric constant of 7 to 8) in a conventional PCM RF switch, the off-state capacitance is reduced, and the figure of merit (FOM) for the PCM RF switch is increased.

Third, the parasitic resistance in the read path due to soft reset is mitigated or prevented. The on-state resistance Rₒₙ is improved accordingly.

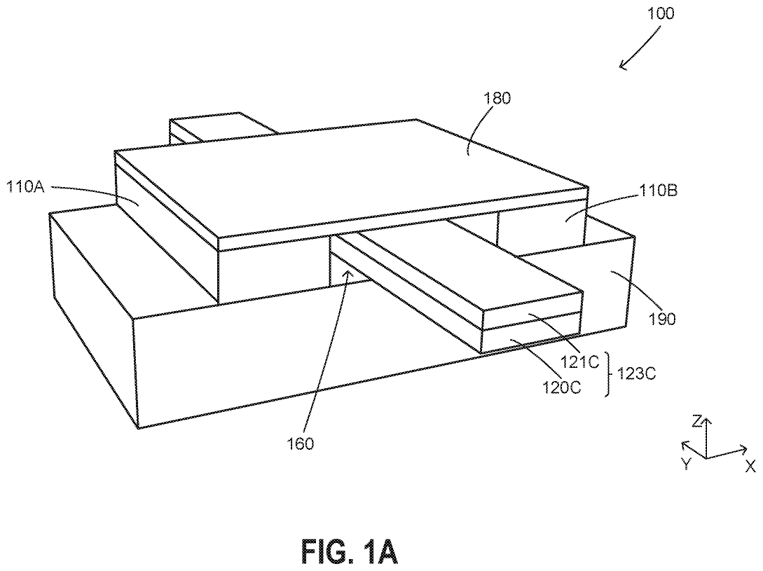

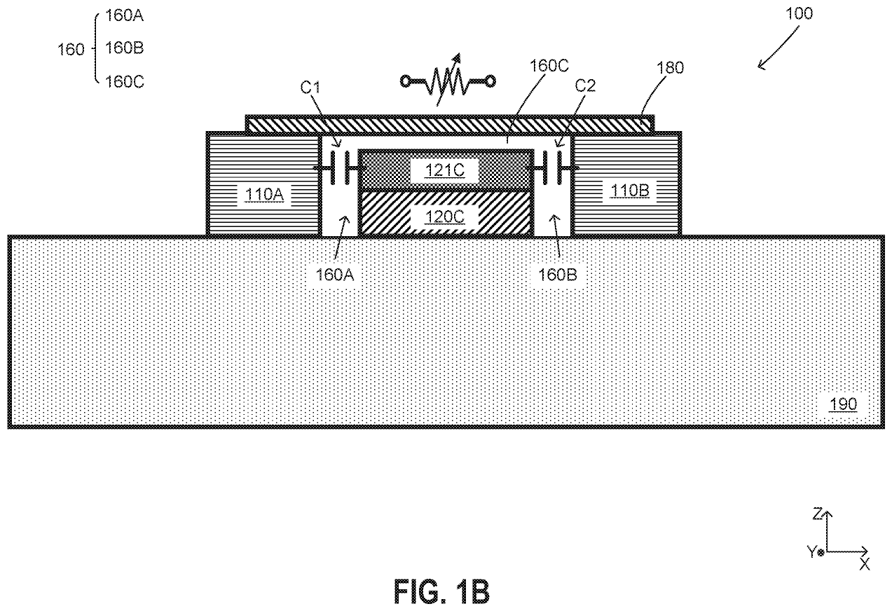

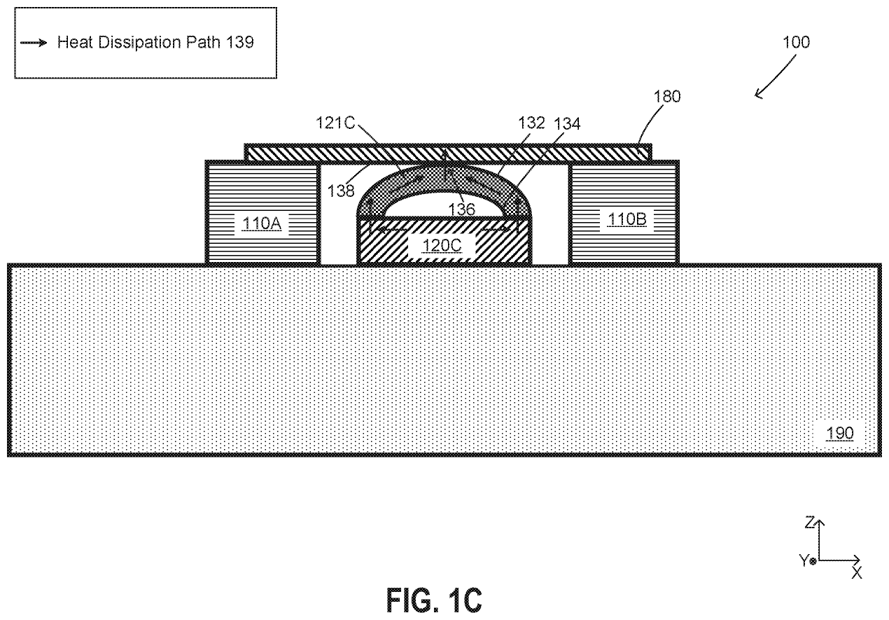

Details of the PCM switching device and these benefits will be described below with references to FIGS. 1A to 6.

### Example PCM RF Switch

FIG. 1A is a diagram illustrating an example PCM RF switch 100 in accordance with some embodiments. FIG. 1A is a perspective view. FIG. 1B is a diagram illustrating the cross-section of the PCM RF switch 100 shown in FIG. 1A in accordance with some embodiments. FIG. 1C is a diagram illustrating the cross-section of the PCM RF switch 100 shown in FIG. 1A during a write operation in accordance with some embodiments. It should be understood that FIGS. 1A and 1B are not drawn to scale.

In the example shown in FIGS. 1A and 1B, the example PCM RF switch 100 includes, among other elements, a base dielectric layer 190, a first heater element 120C, a second heater element 121C, a PCM region 180, two RF pads (sometimes also referred to as “metal pads”) 110A and 110B. The second heater element 121C is disposed on the first heater element 120C, as shown in FIGS. 1A and 1B. The combination of the first heater element 120C and the second heater element 121C may be referred to as a “double-layered heater element” 123C. There is an air gap 160 surrounding the double-layered heater element 123C and between the double-layered heater element 123C and the PCM region 180 and the RF pads 110A and 110B. It should be understood that the PCM RF switch 100 may include other components such as structures electrically connected to the RF pads 110A and 110B.

The first heater element 120C is disposed on the top surface of the base dielectric layer 190. In one embodiment, the base dielectric layer 190 comprises silicon dioxide. In other embodiments, the base dielectric layer 190 comprises other dielectric materials. In one implementation, the base dielectric layer 190 is an interlayer dielectric layer over a semiconductor substrate comprising, for example, silicon. In another implementation, the base dielectric layer 190 is a dielectric layer on the top surface of a semiconductor substrate comprising, for example, silicon. It should be understood that these embodiments and implementations are not intended to be limiting.

In the example shown in FIGS. 1A and 1B, the first heater element 120C is elongated and extends in a first horizontal direction (i.e., the Y-direction). In some implementations, heater pads are located at a first end and a second end of the first heater element 120C, respectively. When a voltage is applied, electric current flows between the heater pads of the first heater element 120C through the first heater element 120C. As mentioned above, the heat generated by the first heater element 120C can be controlled by the electric current.

In the example shown in FIGS. 1A and 1B, the second heater element 121C is disposed on the top surface of the first heater element 120C and extends in the Y-direction. In the example shown in FIGS. 1A and 1B, the second heater element 121C has a substantially the same width in a second horizontal direction (i.e., the X-direction) perpendicular to the first horizontal direction as the first heater element 120C when they are not in the write operation (i.e., no electric current flowing therethrough). The width of the second heater element 121C is substantially same as the width of the first heater element 120C when the difference is smaller than 5%. In one example, the width of the second heater element 121C is the same as the width of the first heater element 120C when they are not in the write operation.

Likewise, in some implementations, heater pads are located at a first end and a second end of the second heater element 121C, respectively. When a voltage is applied, electric current flows between the heater pads of the second heater element 121C through the second heater element 121C. As mentioned above, the heat generated by the second heater element 121C can be controlled by the electric current. In one implementation, the heater pads of the second heater element 121C have the same shape and size in the horizontal plane (i.e., the X-Y plane).

It is advantageous that the material of the first heater element 120C and the material of the second heater element 121C are characterized by a relatively high thermal conductivity and a relatively low electrical resistivity. The relatively high thermal conductivity contributes to better thermal transmission efficiency, whereas the relatively low electrical resistivity contributes to a higher write operation efficiency.

In some embodiments, the candidate materials of the first heater element 120C and the second heater element 121C include tungsten (W), titanium (Ti), aluminum (Al), and tantalum (Ta). Using the coefficient of linear thermal expansion (CLTE) as the measurement, the CLTE of tungsten (W) is 4.5×10⁻⁶ K⁻¹; the CLTE of titanium (Ti) is 8.6×10⁻⁶ K⁻¹; the CLTE of aluminum (Al) is 23.1×10⁻⁶ K⁻¹; the CLTE of tantalum (Ta) is 6.4×10⁻⁶ K⁻¹.

As will be explained below, the CLTE of the second heater element 121C is larger than the CLTE of the first heater element 120C. Therefore, the following combinations can be employed in different embodiments. In one embodiment, the first heater element 120C comprises tungsten (W); the second heater element 121C comprises tantalum (Ta). In another embodiment, the first heater element 120C comprises tungsten (W); the second heater element 121C comprises titanium (Ti). In yet another embodiment, the first heater element 120C comprises tungsten (W); the second heater element 121C comprises aluminum (Al). In still another embodiment, the first heater element 120C comprises tantalum (Ta); the second heater element 121C comprises titanium (Ti). In one embodiment, the first heater element 120C comprises tantalum (Ta); the second heater element 121C comprises aluminum (Al). In another embodiment, the first heater element 120C comprises titanium (Ti); the second heater element 121C comprises aluminum (Al).

The RF pads 110A and 110B are disposed on the base dielectric layer 190. The RF pad 110A is disposed at one side (in the X-direction) of the first heater element 120C and the second heater element 121C with an air gap portion 160A therebetween. The RF pad 110B is disposed at another side (in the X-direction) of the first heater element 120C and the second heater element 121C with an air gap portion 160B therebetween. In other words, the RF pad 110A and the RF pad 110B are disposed on the base dielectric layer 190 at two sides of the first heater element 120C and the second heater element 121C, respectively. Although the RF pads 110A and 110B are covered by the PCM region 180 in the example shown in FIG. 1A, one of ordinary skill in the art would recognize that the RF pads 110A and 110B can extend horizontally, without the coverage of the PCM region 180, to form relatively large areas for pad connection.

The PCM region 180 is disposed on the RF pads 110A and 110B. Two ends of the PCM region 180 in the X-direction are in contact with the RF pads 110A and 110B, respectively. Specifically, a first end of the PCM region 180 in the X-direction is disposed on and electrically connected to the RF pad 110A, and a second end of the PCM region 180 in the X-direction is disposed on and electrically connected to the RF pad 110B. A central region of the PCM region 180 between the first end and the second end is above the top surface 132 of the second heater element 121C with an air gap portion 160C therebetween. The air gap 160 (between the first and second heater elements 120C and 121C and the RF pads 110A and 110B and the PCM region 180) comprises the air gap portions 160A, 160B, and 160C. The air gap 160 surrounds the first heater element 120C and the second heater element 121C from three sides (i.e., the top side and two lateral sides).

As explained above, the resistive states of the PCM region 180 can go through reversible switching between amorphous and crystalline. As the PCM region 180 changes phase between crystalline and amorphous, the PCM RF switch is turned on or turned off accordingly.

In some examples, the PCM region 180 comprises one or more layers of a binary system of Ga—Sb, In—Sb, In—Se, Sb—Te, Ge—Te, and Ge—Sb; a ternary system of Ge—Sb—Te, In—Sb—Te, Ga—Se—Te, Sn—Sb—Te, In—Sb—Ge, and Ga—Sb—Te; a quaternary system of Ag—In—Sb—Te, Ge—Sn—Sb—Te, Ge—Sb—Se—Te, Te—Ge—Sb—S, Ge—Sb—Te—O, and Ge—Sb—Te—N; a chalcogenide alloy containing one or more elements from Group VI of the periodic table, a Ge—Sb—Te alloy, Ge₂Sb₂Te₅, tungsten oxide, nickel oxide, copper oxide, or combinations thereof. In one embodiment, the PCM of the PCM region 180 comprises germanium telluride (GeTe). In one embodiment, the PCM of the PCM region 180 comprises antimony telluride (Sb₂Te₃). It should be understood that these materials are exemplary rather than limiting. In some implementations, the PCM region 180 is formed by chemical vapor deposition (CVD), physical vapor deposition (PVD), pulsed laser deposition (PLD), sputtering, atomic layer deposition (ALD), or any other suitable thin film deposition processes.

The phase transition between the crystalline phase and the amorphous phase of the PCM region 180 is related to the interplay between the long-range order and the short-range order of the structure of the material of the PCM region 180. For example, the collapse of the long-range order generates the amorphous phase. The long-range order in the crystalline phase facilitates electrical conduction, while the amorphous phase impedes electrical conduction and results in high electrical resistance. To tune the properties of the PCM region 180 for different needs, the material of the PCM region 180 may be doped with various elements at different amounts to adjust the proportion of the short-range order and the long-range order inside the bonding structure of the material. The doped element may be any element used for semiconductor doping through the use of, for example, ion implantation or diffusion.

As shown in FIGS. 1A and 1B, each of the RF pads 110A and 110B is in contact with the PCM region 180. Therefore, there is an electrical path (i.e., the read path) from the RF pad 110A, through the PCM region 180, to the RF pad 110B. The read path is separated from the write path. When the PCM region 180 is in the amorphous state, the electrical path is cut off, and the PCM RF switch 100 is turned off. When the PCM region 180 is in the crystalline state, the electrical path is created, and the PCM RF switch 100 is turned on. The resistance in the on-state (i.e., Rₒₙ) is represented by a resistor symbol shown in FIG. 1B.

### Example Write Operation

As shown in FIG. 1C, heat is generated by the first heater element 120C and the second heater element 121C during the write operation. As the first heater element 120C and the second heater element 121C are in contact with each other, and both have a relatively high thermal conductivity, the temperature of the first heater element 120C is close to, or even equal to, in some examples, the temperature of the second heater element 121C. The temperature of the first heater element 120C and the second heater element 121C rises due to the heat generated.

However, the coefficient of thermal expansion (CTE) of the second heater element 121C is larger than the CTE of the first heater element 120C. The CTE of a material is a property that is indicative of the extent to which a material expands upon heating. Different materials have different CTEs. Because the CTE of the second heater element 121C is larger than the CTE of the first heater element 120C, the second heater element 121C expands more than the first heater element 120C upon heating during the write operation. As a result, the second heater element 121C deforms.

In the example shown in FIG. 1C, the second heater element 121C deforms due to the CTE difference. As a result of the deformation of the second heater element 121C, the second heater element 121C protrudes upwardly towards the PCM region 180. The top surface 132 and the bottom surface 134 become curved surfaces instead of flat surfaces. In one example, the top surface 132 and the bottom surface 134 become single-curved surfaces (i.e., the surfaces become curved in the X-direction but not in the Y-direction). The tip 136 (and a small region near the tip 136) of the top surface 132 is in contact with the bottom surface 138 of the PCM region 180. As such, a heat dissipation path 139 (shown as the arrows in FIG. 1C) is created. The heat generated by the current flowing through the second heater element 121C during the write operation is dissipated, in the vertical direction (i.e., the Z-direction shown in FIG. 1C), to the PCM region 180; the heat generated by the current flowing through the first heater element 120C during the write operation is dissipated, through the second heater element 121C, to the PCM region 180.

When the temperature of the PCM region 180 is above the melting temperature of the PCM region 180, the PCM region 180 changes from the crystalline state to the amorphous state and transforms to a high resistance state. When the temperature of the PCM region 180 is above the crystallization temperature, but below the melting temperature of the PCM region 180, the PCM region 180 changes from the amorphous state to the crystalline state and transforms into a low resistance state.

The efficiency of thermal distribution is increased because of the presence of the air gap 160 and the double-layered heater element 123C. There is no conventional dielectric layer between the double-layered heater element 123C and the PCM region 180. As a result, no heat that is generated by the double-layered heater element 123C is absorbed by the conventional dielectric layer. Moreover, since only the tip 136 and a small region near the tip of the top surface 132 of the second heater element 121C are in contact with the bottom surface 138 of the PCM region 180, lateral thermal dissipation is suppressed. Accordingly, the intended thermal transmission in the vertical direction is more concentrated or focused, the thermal transmission efficiency is further increased. The power needed during the write operation is reduced accordingly.

The off-state capacitance C_{off} is reduced. As shown in FIG. 1B, the off-state capacitance C_{off} can be regarded as two capacitors C1 and C2 connected in parallel. For each of the capacitors C1 and C2, the capacitance is determined by the materials between the RF pad 110A/110B and the double-layered heater element 123C. Due to the presence of the air gap 160 (characterized by a relatively low dielectric constant of about 1) instead of the silicon nitride layer made of silicon nitride (characterized by a relatively high dielectric constant of 7 to 8) in a conventional PCM RF switch, the capacitance of the capacitors C1 and C2 is reduced. Accordingly, the off-state capacitance C_{off} is reduced, and the isolation of the PCM RF switch 100 is improved. The figure of merit (FOM) for the PCM RF switch 100, which is proportional to 1/(2π×Rₒₙ×Co_{off}, is increased. Rₒₙ is the on-state resistance. The insertion loss (i.e., the ratio of the output power at the output port to the input power at the input port when the PCM RF switch is turned on) and the isolation (i.e., the ratio of the output power to the input power when the PCM RF switch is turned off) are improved as well.

### Mitigating or Preventing Parasitic Resistance Related to Soft Reset

FIG. 2 is a diagram illustrating soft reset that can be prevented in accordance with some embodiments. FIG. 3 is a diagram illustrating an example equivalent circuit of the PCM region in accordance with some embodiments. As shown in FIG. 2, the PCM resistance varies as the temperature rises in a reset operation implemented during the write operation. In the reset operation (i.e., changing from the crystalline state to the amorphous state), a high current is used to raise the temperature of the PCM above its melting temperature (i.e., Region 3 shown in FIG. 2), with a fast cooling (i.e., a short falling time) to quench the PCM to prevent re-crystallization. However, if the temperature rises but does not reach the melting temperature (i.e., Region 2 shown in FIG. 2), the PCM resistance is lower than the resistance of a fully amorphous PCM.

In a conventional structure, a portion of the PCM region on both sides of the overlapping area between the heater element and the PCM region is soft reset due to the lateral thermal dissipation.

In contrast, the PCM RF switch 100 shown in FIGS. 1A-1C can mitigate or even prevent the soft reset regions from happening because the intended thermal transmission in the vertical direction is more concentrated or focused. Accordingly, as shown in FIG. 3, the read path between the RF port 302 (corresponding to, for example, the RF pad 110A shown in FIG. 1A) and the RF port 304 (corresponding to, for example, the RF pad 110B shown in FIG. 1A) can be regarded as a resistor 312 corresponding to the active PCM region at the center of the PCM region 180 and the resistors 314 and 316 corresponding to the fresh PCM regions at the peripheral regions of the PCM region 180. In other words, the resistors in the conventional structure that correspond to the soft reset regions are eliminated in the equivalent circuit shown in FIG. 3. The parasitic resistance in the read path due to soft reset is mitigated or prevented. The on-state resistance Rₒₙ is improved accordingly.

### Example Process Flow

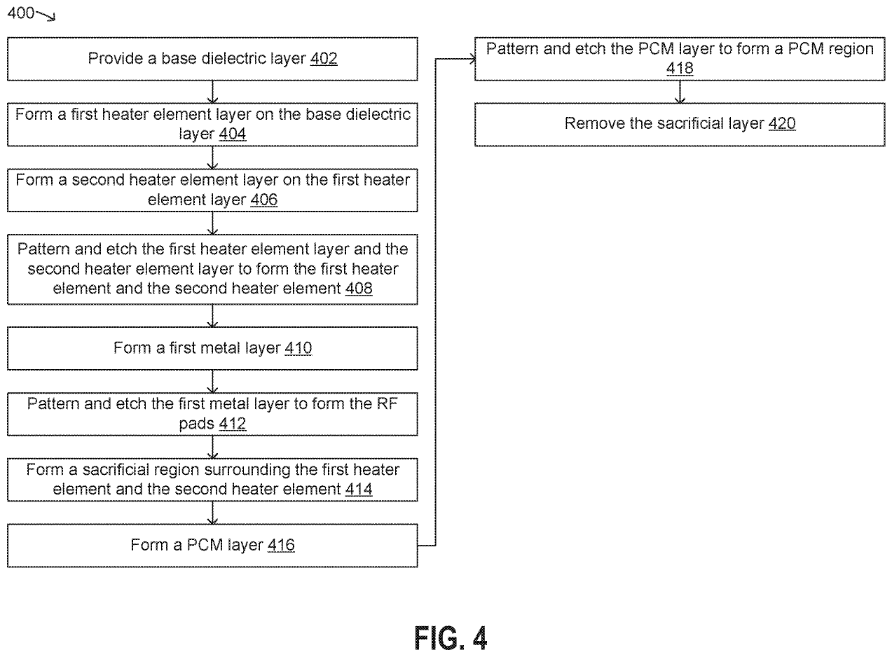

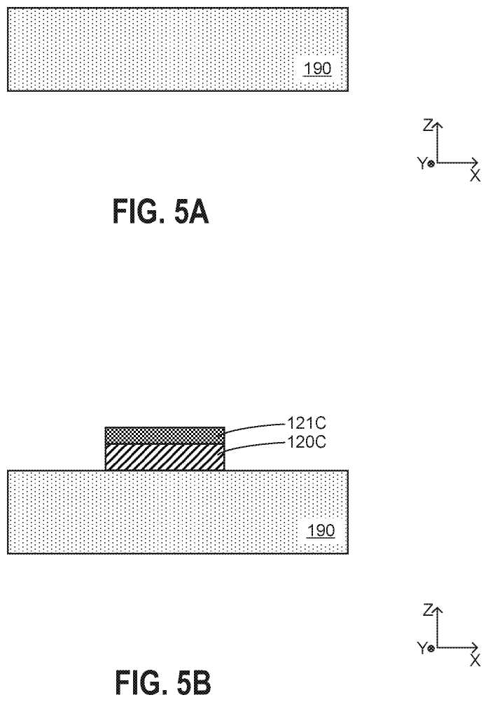

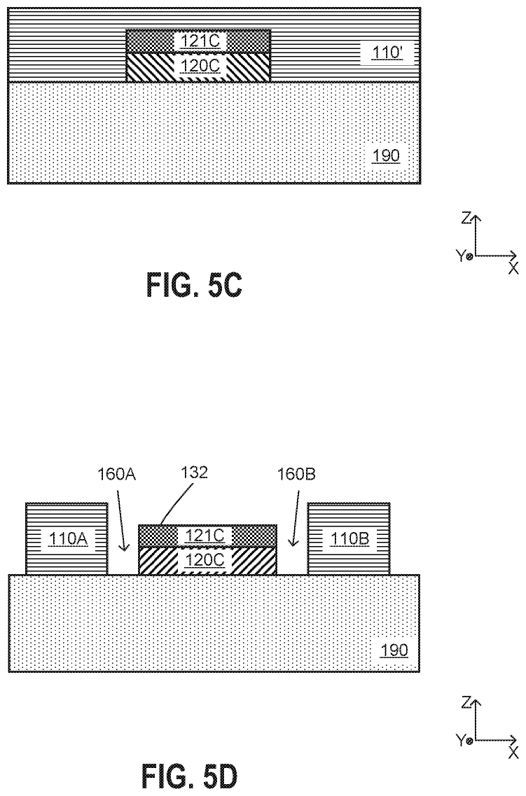

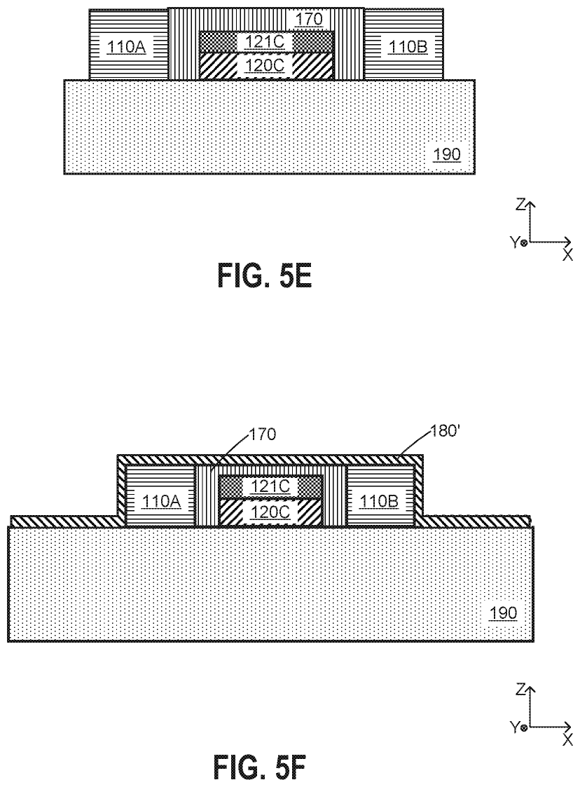

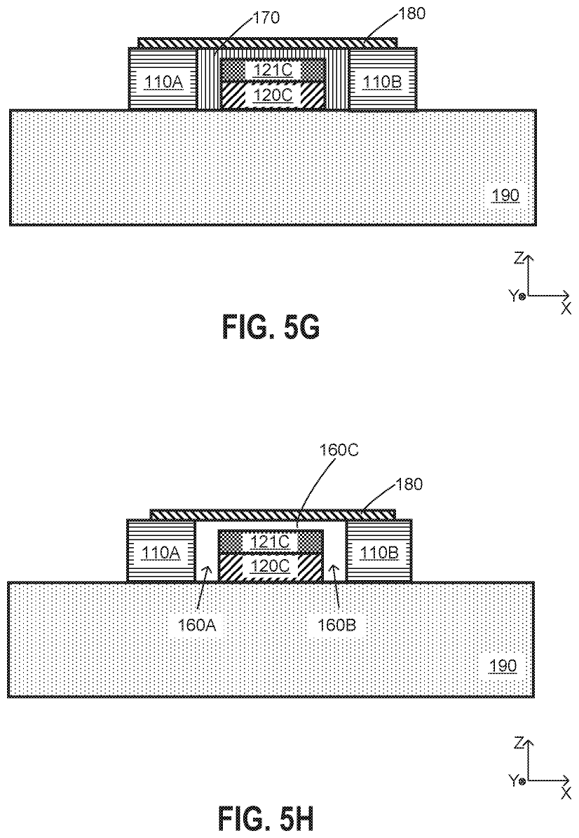

FIG. 4 is a flowchart diagram illustrating an example method 400 for fabricating a PCM RF switch in accordance with some embodiments. In the example shown in FIG. 4, the method 400 includes operations 402, 404, 406, 408, 410, 412, 414, 416, 418, and 420. Additional operations may be performed. Also, it should be understood that the sequence of the various operations discussed above with reference to FIG. 4 is provided for illustrative purposes, and as such, other embodiments may utilize different sequences. These various sequences of operations are to be included within the scope of embodiments. FIGS. 5A-5H are cross-sectional views of a portion of the PCM RF switch at various stages of fabrication in accordance with some embodiments.

The method 400 starts with operation 402. At operation 402, a base dielectric layer is provided. In one implementation, the base dielectric layer is an interlayer dielectric layer over a semiconductor substrate comprising, for example, silicon. In another implementation, the base dielectric layer is a dielectric layer on the top surface of a semiconductor substrate comprising, for example, silicon. It should be understood that these implementations are not intended to be limiting.

In the example shown in FIG. 5A, the base dielectric layer 190 is provided. In one embodiment, the base dielectric layer 190 comprises silicon dioxide characterized by a relatively low thermal conductivity (about 1.4 W/(m·K)), which is beneficial for thermal confinement. In other embodiments, the base dielectric layer 190 comprises other dielectric materials.

At operation 404, a first heater element layer is formed on the base dielectric layer. The first heater element layer comprises a first metal element. The second metal element is characterized by a first CTE. In one implementation, the first heater element layer is formed by chemical vapor deposition (CVD), physical vapor deposition (PVD), pulsed laser deposition (PLD), sputtering, atomic layer deposition (ALD), or any other suitable processes.

At operation 406, a second heater element layer is formed on the first heater element layer. The second heater element layer comprises a second metal element. The second metal element is characterized by a second CTE. The second CTE is larger than the first CTE. In one implementation, the first heater element layer is formed by chemical vapor deposition (CVD), physical vapor deposition (PVD), pulsed laser deposition (PLD), sputtering, atomic layer deposition (ALD), or any other suitable processes.

At operation 408, the second heater element layer and the first heater element layer are patterned and etched to form the second heater element and the first heater element. In one implementation, a photoresist layer is formed on the second heater element layer and then patterned, using photolithography, and the exposed region of the second heater element layer and the first heater element layer is etched subsequently.

In the example shown in FIG. 5B, the first heater element 120C is disposed on the base dielectric layer 190, and the second heater element 121C is disposed on the first heater element 120C after operations 404-408. In the example shown in FIG. 5B, the second heater element 121C has the same width in the X-direction as the first heater element 120C when they are not in the write operation (i.e., no electric current flowing therethrough).

In one embodiment, the first heater element 120C comprises tungsten (W); the second heater element 121C comprises tantalum (Ta). In another embodiment, the first heater element 120C comprises tungsten (W); the second heater element 121C comprises titanium (Ti). In yet another embodiment, the first heater element 120C comprises tungsten (W); the second heater element 121C comprises aluminum (Al). In still another embodiment, the first heater element 120C comprises tantalum (Ta); the second heater element 121C comprises titanium (Ti). In one embodiment, the first heater element 120C comprises tantalum (Ta); the second heater element 121C comprises aluminum (Al). In another embodiment, the first heater element 120C comprises titanium (Ti); the second heater element 121C comprises aluminum (Al).

At operation 410, a first metal layer is formed. In one implementation, the first heater element layer is formed by chemical vapor deposition (CVD), physical vapor deposition (PVD), pulsed laser deposition (PLD), sputtering, atomic layer deposition (ALD), or any other suitable processes. In the example shown in FIG. 5C, the first metal layer 110's is formed.

At operation 412, the first metal layer is patterned and etched to form RF pads. In one implementation, a photoresist layer is formed on the first metal layer and then patterned, using photolithography, and the exposed region of the first metal layer is etched subsequently.

In the example shown in FIG. 5D, the RF pads 110A and 110B are formed on the base dielectric layer 190. The RF pad 110A is disposed lateral to, in the X-direction, the left side of the first heater element 120C and the second heater element 121C with an air gap portion 160A therebetween. The RF pad 110B is disposed lateral to, in the X-direction, the right side of the first heater element 120C and the second heater element 121C with an air gap portion 160B therebetween. The top surface 132 of the second heater element 121C is lower, in the Z-direction, than the top surfaces of the RF pads 110A and 110B.

At operation 414, a sacrificial region is formed. The sacrificial region surrounds the first heater element and the second heater element from the top side and two lateral sides. The sacrificial region is made of a material that is selectively removable in the subsequent sacrificial release process. In one embodiment, the sacrificial region comprises silicon nitride. In another embodiment, the sacrificial region is an organic dielectric layer (ODL). It should be understood that the sacrificial region may comprise other suitable materials in other embodiments. In some implementations, the sacrificial region is formed by forming a sacrificial layer and performing a planarization process such as a chemical-mechanical polishing (CMP) process to remove the excessive portion of the sacrificial layer.

In the example shown in FIG. 5E, the sacrificial region 170 surrounds the first heater element 120C and the second heater element 121C from the top side (in the Z-direction) and two lateral sides (in the X-direction). The air gap portions 160A and 160B shown in FIG. 5D are filled by the sacrificial region 170. The air gap portion 160C shown in FIG. 1B is also filled by the sacrificial region 170.

At operation 416, a PCM layer is formed. The PCM layer is formed on the top surface of the base dielectric layer, the top surface of the RF pads, and the top surface of the sacrificial region. As mentioned above, the PCM layer may comprise one or more layers of a binary system of Ga—Sb, In—Sb, In—Se, Sb—Te, Ge—Te, and Ge—Sb; a ternary system of Ge—Sb—Te, In—Sb—Te, Ga—Se—Te, Sn—Sb—Te, In—Sb—Ge, and Ga—Sb—Te; a quaternary system of Ag—In—Sb—Te, Ge—Sn—Sb—Te, Ge—Sb—Se—Te, Te—Ge—Sb—S, Ge—Sb—Te—O, and Ge—Sb—Te—N; a chalcogenide alloy containing one or more elements from Group VI of the periodic table, a Ge—Sb—Te alloy, Ge₂Sb₂Te₅, tungsten oxide, nickel oxide, copper oxide, or combinations thereof. It should be understood that these materials are exemplary rather than limiting.

In some implementations, the PCM layer is formed by chemical vapor deposition (CVD), physical vapor deposition (PVD), pulsed laser deposition (PLD), sputtering, atomic layer deposition (ALD), or any other suitable thin film deposition processes.

In the example shown in FIG. 5F, the PCM layer 180′ is formed on the top surface of the base dielectric layer 190, the top surface of the RF pads 110A and 110B, and the top surface of the sacrificial region 170.

At operation 418, the PCM layer is patterned and etched to form a PCM region. In one implementation, a photoresist layer is formed on the PCM layer formed at operation 416 and then patterned, using photolithography, and the exposed region of the PCM layer is etched subsequently.

In the example shown in FIG. 5G, the PCM region 180 is formed after patterning and etching the PCM layer 180′ shown in FIG. 5F. As shown in FIG. 5G, the PCM region 180 is disposed on the top surface of the RF pads 110A and 110B and the top surface of the sacrificial region 170.

At operation 420, the sacrificial region is removed. In one implementation, the sacrificial region is removed using the sacrificial release process. As explained above, the sacrificial region is made of a material that is selectively removable in the subsequent sacrificial release process. After the sacrificial region is removed, the air gap is formed.

The sacrificial release process is a process where a structure is formed on the sacrificial region that is later removed to leave a gap between the structure and the structure or layer under the sacrificial region. In some implementations, a release aperture is fabricated using, for example, various lithography and etch techniques. The release aperture then provides access to the sacrificial region for the etchant used in the sacrificial release process. The etchant starts etching through the release aperture and etches its way into the cavity. The size of the release aperture, along with other parameters such as the temperature, determines the etch rate of the sacrificial region and can be designed accordingly. It should be understood that the above examples are not intended to be limiting. In some implementations, multiple release apertures can be used.

In the example shown in FIG. 5H, the sacrificial region 170 shown in FIG. 5G is removed after operation 420. As a result, the air gap portions 160A, 160B, and 160C are formed.

It should be understood that additional operations may be employed in addition to operations 402 to 420. For example, an additional dielectric layer can be formed, patterned, and etched, and vias that are vertically connected to the RF pads 110A and 110B (where the RF pads 110A and 110B are not covered by the PCM region 180) are subsequently formed in the additional dielectric layer.

### Example Operation of the PCM RF Switch

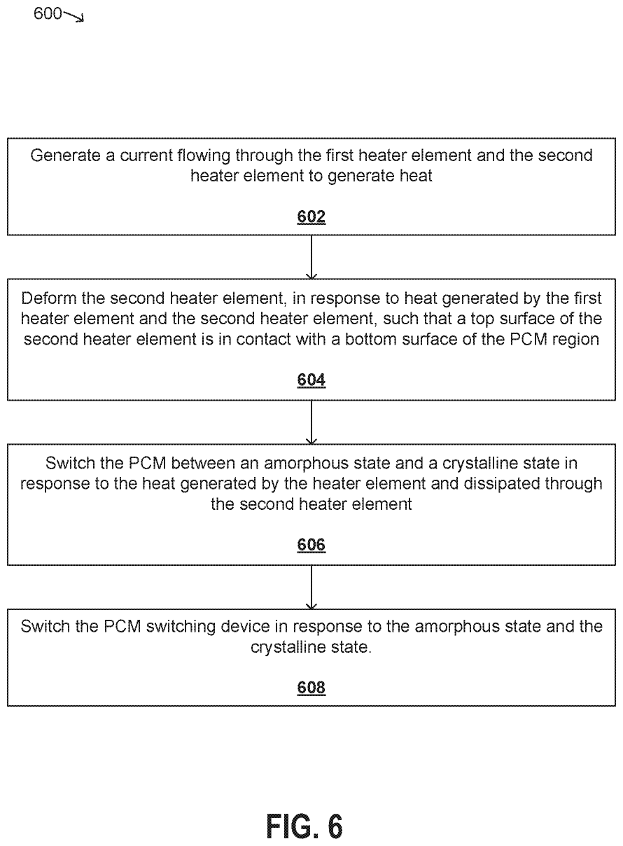

FIG. 6 is a flowchart diagram illustrating an example method 600 for operating a PCM RF switch in accordance with some embodiments. In the example shown in FIG. 6, the method 600 includes operations 602, 604, 606, and 608. Additional operations may be performed.

At operation 602, a current flowing through the first heater element 120C and the second heater element 121C is generated, and heat is generated by the first heater element 120C and the second heater element 121C as a result. In one implementation, the current is generated by applying a bias at two ends of the first heater element 120C and the second heater element 121C.

At operation 604, the second heater element 121C is deformed, in response to the heat generated by the first heater element 120C and the second heater element 121C, such that the top surface 132 of the second heater element 121C is in contact with the bottom surface 138 of the PCM region 180. As such, a heat dissipation path 139 is created.

At operation 606, the PCM of the PCM region 180 is switched between an amorphous state and a crystalline state in response to the heat generated by the first heater element 120C and the second heater element 121C and dissipated through the second heater element 121C. The amorphous state corresponds to a high resistance state. The crystalline state corresponds to a low resistance state.

At operation 608, the PCM switching device (i.e., the PCM RF switch) 100 is switched between an ON state and an OFF state in response to the amorphous state and the crystalline state of the PCM of the PCM region 180. The read path extending in the X-direction is created or cut off accordingly, which can be read from the voltage between the RF pads 110A and 110B.

In accordance with some aspects of the disclosure, a PCM switching device is provided. The PCM switching device includes: a base dielectric layer over a semiconductor substrate; a first heater element disposed on the base dielectric layer, the first heater element comprising a first metal element characterized by a first coefficient of thermal expansion (CTE); a second heater element disposed on the first heater element, the second heater element comprising a second metal element characterized by a second CTE, wherein the second CTE is larger than the first CTE; a first metal pad disposed on the base dielectric layer, wherein the first metal pad is lateral to a first side, in a first horizontal direction, of the first heater element and the second heater element with a first air gap portion therebetween; a second metal pad disposed on the base dielectric layer, wherein the second metal pad is lateral to a second side, in the first horizontal direction, of the first heater element and the second heater element with a second air gap portion therebetween; and a PCM region comprising a PCM operable to switch between an amorphous state and a crystalline state in response to heat generated by the first heater element and the second heater element, wherein the PCM region is above a top surface of the second heater element with a third air gap portion therebetween.

In accordance with some aspects of the disclosure, a method of fabricating a PCM switching device is provided. The method includes the following steps: providing a base dielectric layer; forming a first heater element on the base dielectric layer, the first heater element comprising a first metal element characterized by a first coefficient of thermal expansion (CTE); forming a second heater element on the first heater element, the second heater element comprising a second metal element characterized by a second CTE larger than the first CTE; forming a first metal pad on the base dielectric layer, wherein the first metal pad is lateral to a first side, in a first horizontal direction, of the first heater element and the second heater element with a first air gap portion therebetween; forming a second metal pad on the base dielectric layer, wherein the second metal pad is lateral to a second side, in the first horizontal direction, of the first heater element and the second heater element with a second air gap portion therebetween; and forming a PCM region on the first metal pad and the second metal pad and above a top surface of the second heater element with a third air gap portion therebetween, wherein the PCM region comprises a PCM operable to switch between an amorphous state and a crystalline state in response to heat generated by the first heater element and the second heater element.

In accordance with some aspects of the disclosure, a PCM switching device is provided. The PCM switching device includes: a base dielectric layer over a semiconductor substrate; a first heater element disposed on the base dielectric layer, the first heater element comprising a first metal element characterized by a first coefficient of thermal expansion (CTE); a second heater element disposed on the first heater element, the second heater element comprising a second metal element characterized by a second CTE, wherein the second CTE is larger than the first CTE; a first metal pad and a second metal pad disposed on the base dielectric layer at two sides of the first heater element and the second heater element, respectively; and a PCM region comprising a PCM operable to switch between an amorphous state and a crystalline state in response to heat generated by the first heater element and the second heater element, wherein the PCM region is disposed on the first metal pad and the second metal pad and above a top surface of the second heater element, and an air gap surrounds the first heater element and the second heater element from three sides.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of fabricating a phase-change material (PCM) switching device, the method comprising:
providing a base dielectric layer;
forming a first heater element on the base dielectric layer, the first heater element comprising a first metal element characterized by a first coefficient of thermal expansion (CTE);
forming a second heater element on the first heater element, the second heater element comprising a second metal element characterized by a second CTE larger than the first CTE;
forming a first metal pad on the base dielectric layer, wherein the first metal pad is lateral to a first side, in a first horizontal direction, of the first heater element and the second heater element with a first air gap portion therebetween;
forming a second metal pad on the base dielectric layer, wherein the second metal pad is lateral to a second side, in the first horizontal direction, of the first heater element and the second heater element with a second air gap portion therebetween; and
forming a PCM region on the first metal pad and the second metal pad and above a top surface of the second heater element with a third air gap portion therebetween, wherein the PCM region comprises a PCM operable to switch between an amorphous state and a crystalline state in response to heat generated by the first heater element and the second heater element.

2. The method of claim 1, further comprising:
forming a sacrificial region in the first air gap portion, the second air gap portion; and
the third air gap portion; and removing the sacrificial region.

3. The method of claim 2, wherein the removing the sacrificial region comprises:
etching the sacrificial region.

4. The method of claim 3, wherein the etching the sacrificial region is through at least one release aperture providing access to the sacrificial region.

5. The method of claim 1, wherein the second heater element is operable to deform in response to the heat generated by the first heater element and the second heater element.

6. The method of claim 5, wherein the second heater element is operable to deform such that the top surface of the second heater element protrudes upwardly towards the PCM region.

7. The method of claim 6, wherein the second heater element is operable to deform such that the top surface of the second heater element is in contact with a bottom surface of the PCM region.

8. The method of claim 1, wherein the first heater element comprises tungsten, and the second heater element comprises tantalum.

9. A method of fabricating a phase-change material (PCM) switching device, the method comprising:
providing a base dielectric layer;
forming a first heater element on the base dielectric layer, the first heater element comprising a first metal element characterized by a first coefficient of thermal expansion (CTE);
forming a second heater element on the first heater element, the second heater element comprising a second metal element characterized by a second CTE larger than the first CTE;
forming a first metal pad on the base dielectric layer, wherein the first metal pad is lateral to a first side, in a first horizontal direction, of the first heater element and the second heater element;
forming a second metal pad on the base dielectric layer, wherein the second metal pad is lateral to a second side, in the first horizontal direction, of the first heater element and the second heater element;
forming a sacrificial region in a first air gap portion between the first metal pad and the first side, in a second air gap portion between the second metal pad and the second side, and in a third air gap portion above a top surface of the second heater element;
forming a PCM region on the first metal pad and the second metal pad and on a top surface of the sacrificial region, wherein the PCM region comprises a PCM operable to switch between an amorphous state and a crystalline state in response to heat generated by the first heater element and the second heater element; and
removing the sacrificial region.

10. The method of claim 9, wherein the sacrificial region comprises silicon nitride or an organic dielectric layer.

11. The method of claim 9, wherein removing the sacrificial region comprises:
etching the sacrificial region.

12. The method of claim 11, wherein etching the sacrificial region is through at least one release aperture providing access to the sacrificial region.

13. The method of claim 9, wherein the second heater element is operable to deform in response to the heat generated by the first heater element and the second heater element.

14. The method of claim 9, wherein the first heater element comprises tungsten, and the second heater element comprises titanium.

15. A method of fabricating a phase-change material (PCM) switching device, the method comprising:
providing a base dielectric layer;
forming a first heater element on the base dielectric layer, the first heater element comprising a first metal element characterized by a first coefficient of thermal expansion (CTE);
forming a second heater element on the first heater element, the second heater element comprising a second metal element characterized by a second CTE larger than the first CTE;
forming a first metal pad on the base dielectric layer, wherein the first metal pad is lateral to a first side, in a first horizontal direction, of the first heater element and the second heater element with a first air gap portion therebetween;
forming a second metal pad on the base dielectric layer, wherein the second metal pad is lateral to a second side, in the first horizontal direction, of the first heater element and the second heater element with a second air gap portion therebetween; and
forming a PCM region on the first metal pad and the second metal pad and above a top surface of the second heater element with a third air gap portion therebetween, wherein the PCM region comprises a PCM operable to switch between an amorphous state and a crystalline state in response to heat generated by the first heater element and the second heater element, and wherein the second heater element is formed such that it is operable to deform in response to the heat such that the top surface of the second heater element protrudes upwardly to establish contact with a bottom surface of the PCM region.

16. The method of claim 15, further comprising:
forming a sacrificial region in the first air gap portion, the second air gap portion, and the third air gap portion; and
removing the sacrificial region.

17. The method of claim 15, wherein the second heater element is operable to deform such that the top surface of the second heater element becomes a curved surface.

18. The method of claim 17, wherein the curved surface protrudes upwardly towards the PCM region.

19. The method of claim 15, wherein the PCM comprises at least one of germanium telluride and antimony telluride.

20. The method of claim 15, wherein the first heater element comprises tantalum, and the second heater element comprises titanium.
